(19) United States
(12) Patent Application Publication
(10) Pub. No.: US 2007/0045804 A1
(43) Pub. Date: Mar. 1, 2007

(54) Printed circuit board for thermal dissipation and electronic device using the same

(75) Inventors: Chih-Hsiung Lin, Taipei (TW); Nai-Shung Chang, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: VIA Technologies Inc.

(21) Appl. No.: 11/292,631

(22) Filed: Dec. 2, 2005

(30) Foreign Application Priority Data
Aug. 29, 2005 (TW) 94129461

(51) Int. Cl. H01L 23/02

(52) U.S. Cl. 257/686

(57) ABSTRACT

A printed circuit board (PCB) with an improved thermal dissipating structure for a package substrate of a multi-package module (MPM). A first upper metal layer is on a substrate and corresponds to the package substrate. A second upper metal layer is on the substrate outside the package substrate. An inner metal layer is in the substrate. Pluralities of first and second heat conductive vias are in the substrate to thermally connect the inner metal layer to the first and second upper metal layers, respectively. An electronic device with an improved thermal dissipating structure is also disclosed.

### BACKGROUND

The invention relates to an electronic device and in particular to a printed circuit board (PCB) for a multi-package module for thermal dissipation and an electronic device using the same.

Demand for small, high performance portable electronic products such as mobile phones, portable computers, and the like have driven the industry to increase integration on semiconductor dice. Accordingly, the industry is achieving higher integration by turning to 3D packaging by combining assembly technologies including wire bonding or flip chip to stack die packages to form a multi-package module (MPM).

MPM, a current assembly technology, integrates different dice functions, such as microprocessors or memory, logic, optic ICs, instead of placing individual packages onto a large printed circuit board (PCB). MPM, however, has a much higher power density than an individual single die package. Thus, thermal management is a key factor in its successful development.

FIG. 1 illustrates a conventional electronic device 100 with an MPM. The electronic device 100 comprises an MPM 20 mounted on a PCB 101, comprising a package substrate 12. The upper and lower surfaces of the package substrate 12 have dice 16 and 14 with different functions thereon, respectively, to create the MPM 20. For example, the die 16 is mounted on the upper surface of the package substrate 12 by bumps (or solder balls) of a package substrate 12′. The die 14 is mounted on the lower surface of the package substrate 12 by flip chip. The lower surface of the package substrate 12 comprises a plurality of bumps 10 thereon to correspondingly connect to the bonding pads (not shown) on the PCB 101. In the MPM 20, heat generated from the die 16 can be dissipated by radiation and convection. The gap between the die 14 and the PCB 101 is too narrow, however, to dissipate the generated heat by radiation and convection. Accordingly, the heat generated from the die 14 is dissipated by conduction only. Typically, a metal layer 102 is disposed on the PCB 101 corresponding to the die 14 and connected to the die 14 by a heat conductive paste 22. That is, thermal dissipation is accomplished by a thermal conductive path created by the heat conductive paste 22, the metal layer 102 and the PCB 101.

Passive cooling, however, cannot provide an adequate rate of thermal dissipation for high power dice which may generate higher heat. That is, generated heat cannot be rapidly dissipated from dice by conducting the heat to the PCB through the heat conductive paste and the metal layer.

### SUMMARY

A printed circuited board for a package substrate of a multi-package module and an electronic device using the same are provided. An embodiment of a printed circuit board for a package substrate of a multi-package module comprises a substrate, first and second upper metal layers, an inner metal layer and pluralities of first and second heat conductive vias. The first upper metal layer is on the substrate and corresponds to the package substrate. The second upper metal layer is on the substrate and outside the package substrate. The inner metal layer is in the substrate. The first heat conductive vias are in the substrate and thermally connect the first upper metal layer and the inner metal layer. The heat conductive vias are in the substrate and thermally connect the second upper metal layer and the inner metal layer.

An exemplary embodiment of an electronic device comprises a package substrate, comprising a substrate having a die region and an array of bumps arranged on the substrate and surrounding the die region. A circuit board comprises an inner metal layer therein and a plurality of bonding pads correspondingly connected to the bumps. A heat conductive layer is between the die region of the package substrate and the circuit board, thermally contacting the inner metal layer. A heat sink is disposed on the circuit board outside the package substrate, thermally contacting the inner metal layer.

Another embodiment of an electronic device comprises a package substrate, comprising a substrate having a die region and an array of bumps arranged on the substrate and surrounding the die region. A printed circuit board is under the package substrate, comprising a plurality of bonding pads correspondingly connected to the bumps, a first upper metal layer corresponding to die region of the package substrate, a second upper metal layer outside the package substrate and an inner metal layer thermally contact the first and second upper metal layers, respectively.

### DESCRIPTION OF THE DRAWINGS

The invention will become more fully understood from the detailed description given hereinbelow and the accompanying drawings, given by way of illustration only and thus not intended to be limitative of the invention.

FIG. 1 is a cross-section of a conventional electronic device with a multi-package module.

FIG. 2A is a planar view of an embodiment of an electronic device with a thermal dissipating structure.

FIG. 2B is a cross-section along line 2B-2B of FIG. 2A.

FIG. 2C is a planar view of an embodiment of a heat sink with alternately arranged fins.

FIG. 2D is a planar view of an embodiment of a heat sink with triangular fins.

FIG. 2E is a planar view of an embodiment of a heat sink with rectangular fins.

FIG. 3A is a planar view of an embodiment of an electronic device with a thermal dissipating structure.

FIG. 3B is a cross-section along line 3B-3B of FIG. 3A.

FIG. 3C is a planar view of an embodiment of a metal layer with alternately arranged fins.

FIG. 3D is a planar view of an embodiment of a metal layer with triangular fins.

FIG. 3E is a planar view of an embodiment of a metal layer with rectangular fins.

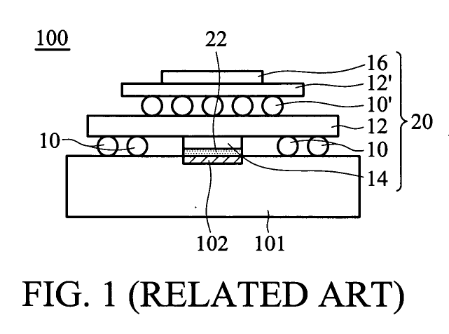

### DETAILED DESCRIPTION

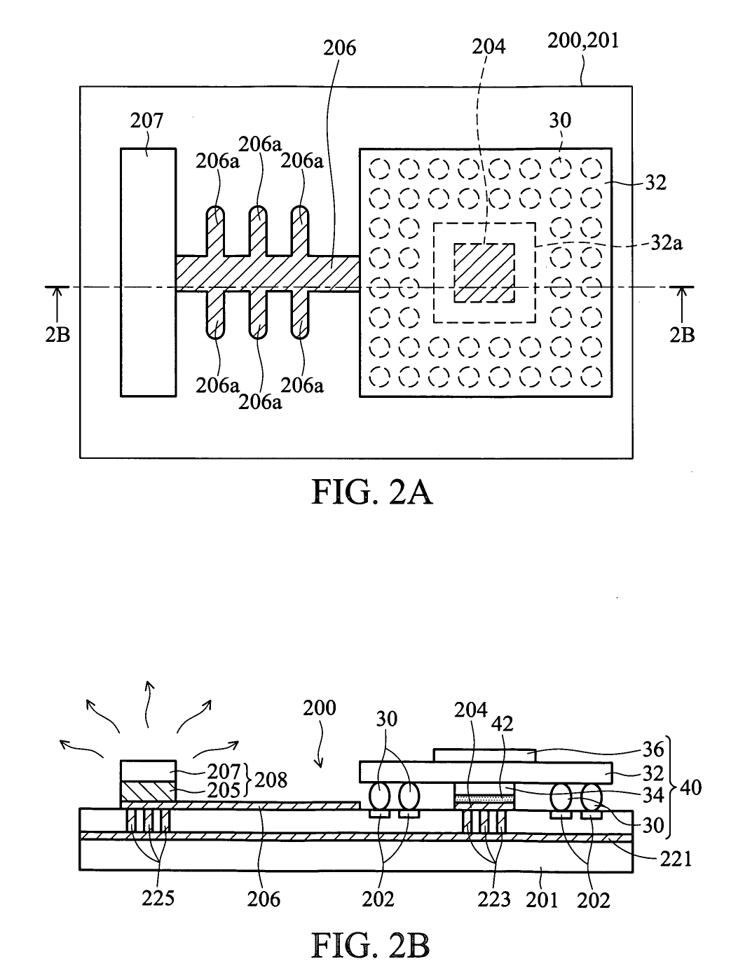

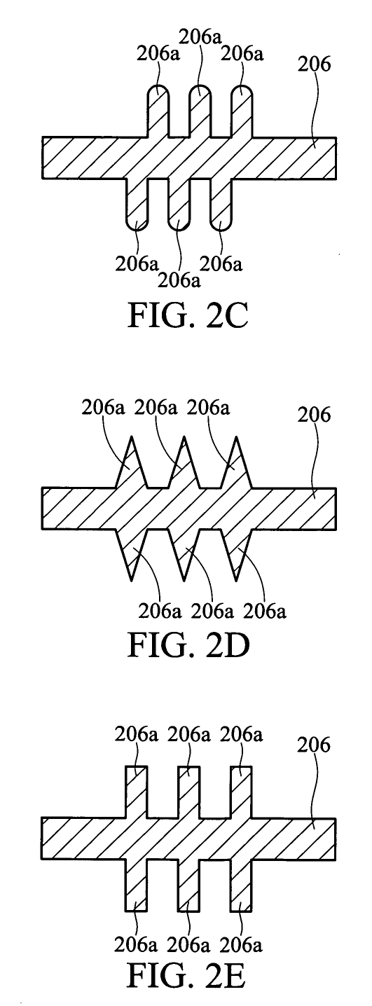

An electronic device for a multi-package module (MPM) for thermal dissipation will now be described in greater detail. FIGS. 2A and 2B illustrate an embodiment of an electronic device with an MPM, wherein FIG. 2A is a planar view of the electronic device and FIG. 2B is a cross-section along line 2B-2B of FIG. 2A. The electronic device comprises an MPM 40, a circuit board 200, a heat conductive layer 204 and a heat sink 206.

The MPM 40 comprises a package substrate 32. The lower surface of the package substrate 32 has a die region 32a and the upper surface of the package substrate 32 also has a die region (not shown). Here, the lower surface represents a surface facing the surface of a circuit board, such as a printed circuit board (PCB), and the upper surface represents the surface opposite to the lower surface. In this embodiment, the package substrate 32 may comprise plastic, ceramic, inorganic or organic material. Typically, the die region 32a is substantially at the center of the package substrate 32. Dice 34 and 36 with different functions may be respectively mounted in the die region 32a of the lower surface and that of the upper surface of the package substrate 32 by the same or different electronic packages. For example, dice 34 and 36 may respectively be mounted on the package substrate 32 by flip chip or wire bonding. An array of bumps 30, such as metal bump, solder balls, signal balls or similar, is arranged on the lower surface of the package substrate 32 and surrounds the die region 32a, to transport signals to external circuits from the dice 34 and 36.

A circuit board 200, such as a PCB, is under the MPM 40 and comprises a substrate 201, an inner metal layer 221 in the substrate 201 and a plurality of bonding pads 202 on the substrate 201, correspondingly connected to the bumps 30 of the MPM 40, thereby electrically connecting the circuit board 200 and the dice 34 and 36. Typically, the circuit board 200 comprises at least one or more metal layers and at least one or more insulating layers, in which the metal layer may serve as a signal layer, a power layer, and/or a grounding layer. In order to simplify the diagram, a flat substrate 201 and an inner metal layer 221 therein are depicted.

A heat conductive layer 204 is disposed on the circuit board 200 and between the circuit board 200 and the package substrate 32. In this embodiment, the heat conductive layer 204 corresponds to the die region 32a of the package substrate 32, thermally contacting the die 34 and the inner metal layer 221 by a heat conductive paste 42 and a plurality of first heat conductive vias 223 in the substrate 201, respectively. The first heat conductive vias 223 may comprise metal.

A heat sink 206 is disposed on the circuit board 200 outside the package substrate 32, thermally contacting the metal layer 221 by a plurality of second heat conductive vias 225 in the substrate 201. The second heat conductive vias 225 may comprise metal. In this embodiment, the heat sink 206 comprises at least one fin 206a. For example, the heat sink 206 on the circuit board 200 outside the package substrate 32 comprises a plurality of round fins 206a which are symmetrically arranged on both sides of the heat sink 206. Moreover, the fins 206a extend substantially parallel to the surface of the circuit board 200. In some embodiments, the fins 206a may be alternately arranged on both sides of the heat sink 206, as shown in FIG. 2C. Additionally, in some embodiments, the fins 206a may be triangular (as shown in FIG. 2D), rectangular (as shown in FIG. 2E) or polygonal (not shown). It will be apparent to those skilled in the art that the triangular or rectangular fins 206a may be alternately arranged on both sides of the heat sink 206, but it is to be understood that the invention is not limited to FIGS. 2D and 2E. In this embodiment, the heat conductive layer 204 or the heat sink 206 may comprise gold, silver or copper. Moreover, the heat conductive layer 204 may partially or fully overlap the die 34. Here, only an example of the full overlap is depicted.

A thermal dissipating module 208 is disposed on the end of the heat sink 206 outside the package substrate 32, providing active thermal dissipation. In this embodiment, the thermal dissipating module 208 may comprise a fan 207 and an underlying heat dissipating component 205, such as a heat plate or pipe.

According to the electronic device of the invention, the inner metal layer 221 and the first and second heat conductive vias 223 and 225 create a virtual thermal channel, such that heat generated from the die 34 on the lower surface of the package substrate 32 can be dissipated by radiation, convection and conduction through the virtual thermal channel and fins 206a of the heat sink 206 outside the package substrate 32 for passive cooling. At the same time, the heat can be effectively and rapidly dissipated to the ambient environment by radiation, convection and conduction through the dissipating component 205, as shown by the arrows in FIG. 2B. Additionally, if the die 34 is a high power die, the heat can be dissipated quickly by the fan 207 for active cooling. Compared to conventional thermal dissipation by conduction of the circuit board, the electronic device with MPM 40 of the invention has better thermal dissipation and a higher thermal dissipation rate.

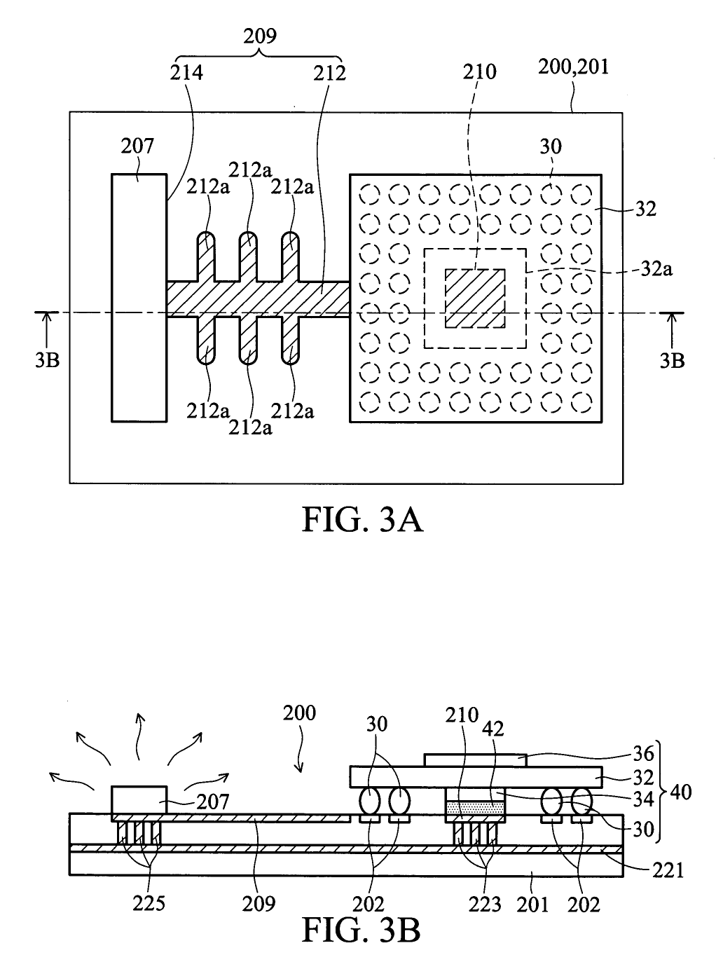

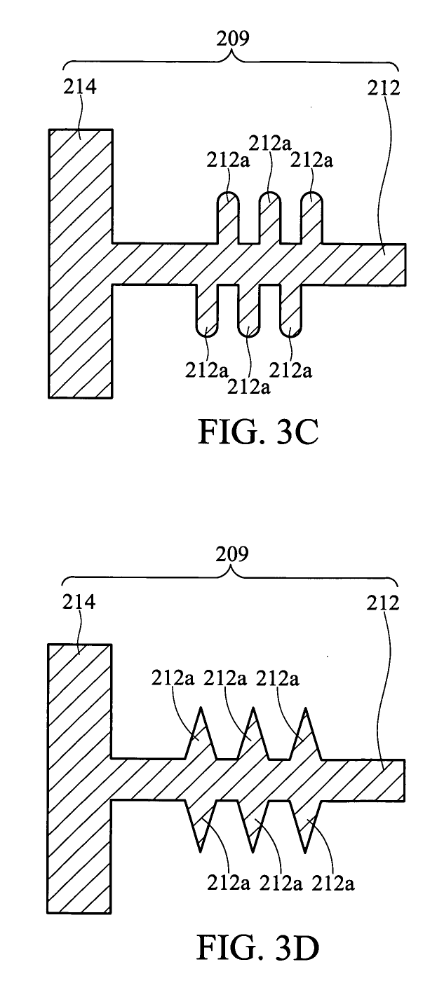

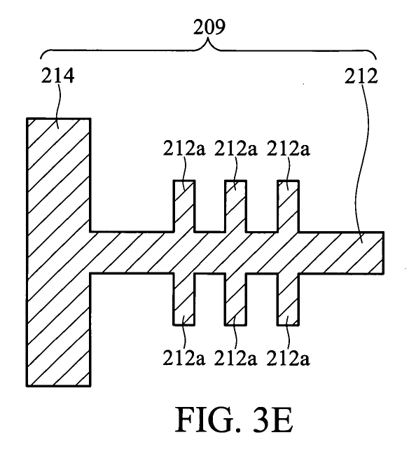

FIGS. 3A and 3B illustrate an embodiment of an electronic device with a thermal dissipating structure, wherein FIG. 3A is a planar view of the electronic device and FIG. 3B is a cross-section along line 3B-3B of FIG. 3A. The same reference numbers as FIGS. 2A and 2B are used, wherefrom like descriptions are omitted. Unlike the embodiment of FIGS. 2A and 2B, the thermal conductive path is formed by the first and second upper metal layers 210 and 209 and the inner metal layer 221 in the circuit board 200. Here, the circuit board 200, such as a PCB, comprises a substrate 201, first and second upper metal layers 210 and 209 and an inner metal layer 221. The second upper metal layer 209 is disposed on the substrate 201, comprising a first portion 212 and a second portion 214.

The first upper metal layer 210 is disposed on the substrate 201 and corresponds to the overlying die region 32a of the package substrate 32. Moreover, the first upper metal layer 210 thermally contacts the die 34 by the heat conductive paste 42 and thermally connects to the inner metal layer 221 by a plurality of first heat conductive vias 223, such as metal vias.

The first portion 212 of the second upper metal layer 209 is on the circuit board 200 outside the package substrate 32 and thermally connects the inner metal layer 221 by a plurality of second heat conductive vias 225, such as metal vias. The first portion 212 of the second upper metal layer 209 comprises at least one fin 212a. The second portion 214 of the second upper metal layer 209 is adjacent to the end of the first portion 212. For example, the first portion 212 of the second upper metal layer 209 comprises a plurality of round fins 212a which are symmetrically arranged on both sides thereof. Moreover, the fins 212 extend substantially parallel to the surface of the substrate 201. In some embodiments, the fins 212a may be alternately arranged on both sides of the first portion 212, as shown in FIG. 3C. Additionally, in some embodiments, the fins 212a may be triangular (as shown in FIG. 3D), rectangular (as shown in FIG. 3E) or polygon (not shown). It will be apparent to those skilled in the art that the triangular or rectangular fins 212a may be alternately arranged on both sides of the first portion 212 and it is to be understood that the invention is not limited to FIGS. 3D and 3E. In this embodiment, the second upper metal layer 209 comprises gold, silver or copper. In this embodiment, the first portion 212 of the second upper metal layer 209 serves as a heat sink. Generated heat from the die 34 can be conducted outside the package substrate 32 by the heat conductive paste 42, the first upper metal layer 210, the first and second heat conductive vias 223 and 225, the inner metal layer 221 and the heat sink for passive cooling. Moreover, the second portion 214 of the second upper metal layer 209 serves as a heat dissipating component to dissipate heat to the ambient environment by a fan 207 disposed thereon for active cooling, as shown by the arrows in FIG. 3B.

In this embodiment, the inner metal layer 221 and the first and second heat conductive vias 223 and 225 create a virtual thermal channel, such that heat generated from the die 34 on the lower surface of the package substrate 32 can be effectively and rapidly dissipated by radiation, convection and conduction through the virtual thermal channel and the heat sink outside the package substrate 32 for passive cooling. Compared to the conventional thermal dissipation by conduction of the circuit board, the electronic device of the invention has better thermal dissipation and a higher thermal dissipation rate. Moreover, since the first and second upper metal layers 210 and 209 are included in the circuit board 200, no additional heat sink or heat dissipating component are required, thus fabrication costs are reduced.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An electronic device, comprising:
a package substrate, comprising:
a substrate having a die region; and
an array of bumps arranged on the substrate and surrounding the die region;
a circuit board comprising a plurality of bonding pads correspondingly connected to the bumps and an inner metal layer therein;
a heat conductive layer between the die region of the package substrate and the circuit board, thermally contacting the inner metal layer; and
a heat sink disposed on the circuit board outside the package substrate and thermally contacting the inner metal layer.

2. The electronic device as claimed in claim 1, wherein the heat sink comprises at least one fin extending substantially parallel to the surface of the circuit board.

3. The electronic device as claimed in claim 2, wherein the fin is round, triangular, rectangular or polygonal.

4. The electronic device as claimed in claim 1, wherein the heat sink comprises a plurality of fins symmetrically or alternately arranged on both sides thereof.

5. The electronic device as claimed in claim 1, further comprising a thermal dissipating module disposed on the heat sink.

6. The electronic device as claimed in claim 5, wherein the thermal dissipating module comprises a heat plate or pipe.

7. The electronic device as claimed in claim 1, wherein the heat sink or the heat conductive layer comprises gold, silver or copper.

8. The electronic device as claimed in claim 1, wherein the circuit board further comprises a plurality of heat conductive vias to thermally connect to the inner metal layer, the heat conductive layer and the heat sink.

9. An electronic device, comprising:
a package substrate, comprising:
a substrate having a die region; and
an array of bumps arranged on the substrate and surrounding the die region; and
a printed circuit board under the package substrate, comprising:
a plurality of bonding pads correspondingly connected to the bumps;
a first upper metal layer corresponding to die region of the package substrate;
a second upper metal layer outside the package substrate; and
an inner metal layer thermally contacting the first and second upper metal layers, respectively.

10. The electronic device as claimed in claim 9, wherein the second upper metal layer comprises at least one fin extending substantially parallel to the surface of the circuit board.

11. The electronic device as claimed in claim 10, wherein the fin is round, triangular, rectangular or polygonal.

12. The electronic device as claimed in claim 9, wherein the second upper metal layer comprises a plurality of fins symmetrically or alternately arranged on both sides thereof.

13. The electronic device as claimed in claim 9, further comprising a thermal dissipating module disposed on the second upper metal layer.

14. The electronic device as claimed in claim 9, wherein the thermal dissipating module comprises a heat plate or pipe.

15. The electronic device as claimed in claim 9, wherein the printed circuit board further comprises a plurality of heat conductive vias to thermally connect to the inner metal layer and the first and second upper metal layers.

16. A printed circuit board for a package substrate of a multi-package module, comprising:
a substrate;
a first upper metal layer on the substrate, corresponding to the package substrate;
a second upper metal layer on the substrate and outside the package substrate;
an inner metal layer in the substrate;
a plurality of first heat conductive vias in the substrate, thermally connecting the first upper metal layer and the inner metal layer; and
a plurality of second heat conductive vias in the substrate, thermally connecting the second upper metal layer and the inner metal layer.

17. The printed circuit board as claimed in claim 16, wherein the second upper metal layer comprises at least one fin extending substantially parallel to the surface of the substrate.

18. The printed circuit board as claimed in claim 17, wherein the fin is round, triangular, rectangular or polygonal.

19. The printed circuit board as claimed in claim 16, wherein the second upper metal layer comprises a plurality of fins symmetrically or alternately arranged on both sides thereof.

20. The printed circuit board as claimed in claim 16, wherein the first or second upper metal layer comprises gold, silver or copper.
